(19) United States
(12) Patent Application Publication
(10) Pub. No.: US 2026/0343804 A1
(43) Pub. Date: Oct. 29, 2026

(54) COOLING DEVICE, THROUGH WHICH A FLUID CAN FLOW, FOR COOLING AN ELECTRICAL AND/OR ELECTRONIC ASSEMBLY

(71) Applicant: Robert Bosch GmbH, Stuttgart (DE)

(72) Inventors: Daniel Michael Stehlik, Moessingen (DE); Patrick Gaiser, Reutlingen (DE); Ralph Grueninger, Sonnenbuehl (DE)

(21) Appl. No.: 19/150,300

(22) PCT Filed: Jan. 19, 2024
(86) PCT No.: PCT/EP2024/051274

§ 371 Date: Jul. 23, 2025

(30) Foreign Application Priority Data
Feb. 6, 2023 (DE) 10 2023 200 941.2

(51) Int. Cl. H05K 7/20

(52) U.S. Cl. CPC H05K 7/20272

(57) ABSTRACT

The present invention relates to a cooling device (100), through which a fluid can flow, for cooling an electrical and/or electronic assembly (200). The cooling device (100) comprises a cooling channel (103), through which a fluid can flow,
and a cooling structure (106), which is arranged in the cooling channel (103). The inner surface (1; 2) of the wall (111; 112) of the cooling channel (103) has a connecting region (6) and an edge region (5). The connecting region (6) is connected to the cooling structure (106), wherein the edge region (5) is not connected to the cooling structure (106).

### BACKGROUND

The present invention relates to a cooling device, through which a fluid can flow, for cooling an electrical and/or electronic assembly, as well as an electrical and/or electronic device having such a cooling device and at least one electrical and/or electronic assembly.

Power modules, such as inverter structures or converter structures, are used in hybrid vehicles or electric vehicles. For example, inverters that provide phase currents to the electric machine are used to operate an electric machine. The power modules can, for example, comprise a support substrate with conductor tracks on which, for example, power semiconductors are arranged which, together with the support substrate, form an electronic unit. During operation, heat is generated by the electrical unit, which must be dissipated. For this purpose, the electronic unit is thermally connected to a cooling device. It is known to provide a cooling device with cooling channels in which a coolant can flow which dissipates the heat from the cooling device. Turbulence structures, for example turbulence inserts, may be provided in the cooling channel of the cooling device, which provide better heat dissipation from the cooling device to the coolant flowing through the cooling device. The turbulence structures generate turbulent flows and increase the cooling surface.

### SUMMARY

The cooling device, through which a fluid can flow, according to the invention for cooling an electrical and/or electronic assembly has the advantage that a more stable connection of the electrical and/or electronic assembly to the cooling device can be achieved with a good cooling performance. This is achieved by a partial connection of a cooling structure, in particular a turbulence insert, to a region of the cooling device, since stress can thus be lowered in at least one connecting layer connecting the electrical and/or electronic assembly to the cooling device. Thus, potential cracks in the at least one bonding layer may be avoided or crack progress may be slowed, thereby maintaining the layer's connectivity. The cooling device, through which a fluid can flow, for cooling an electrical and/or electronic assembly comprises a cooling channel, through which a fluid can flow, and a cooling structure arranged in the cooling channel. An inner surface of a wall of the cooling channel has a connecting region and an edge region, wherein the connecting region is connected to the cooling structure and the edge region is not connected to the cooling structure. In particular, the connecting region is connected to the cooling structure in a material-locking fashion. In other words, the connection of the cooling structure to the inner surface of the wall of the cooling channel in the edge region is separated/prevented. That is in particular to say that only the connecting region is connected to the cooling structure. By this, stresses that may be caused by different thermal expansion coefficients of components of the cooling device, for example the wall(s) of the cooling channel and cooling structure, and/or the electrical and/or electronic assembly and/or the at least one connecting layer, are reduced. Thus, the resulting different elongation/bending can also be reduced to the at least one connecting layer. Thus, it is possible to avoid breaking or reducing the contact between the electrical and/or electronic assembly and the cooling device, otherwise this would result in no or at least inefficient cooling of the electrical and/or electronic assembly. The edge region advantageously extends in the longitudinal direction and width direction of the cooling device and/or the cooling channel. Preferably, the longitudinal direction corresponds to a flow direction of the fluid in/through the cooling channel. It is to be understood that the inner surface of the wall is advantageously facing the cooling channel. It is further to be understood that the edge region advantageously corresponds to a region of the inner surface that extends from one end of the inner surface of the wall of the cooling channel or begins at one end of the inner surface of the wall of the cooling channel. Advantageously, the entire edge region faces the cooling channel. The inner surface of the wall of the cooling channel may preferably also comprise two edge regions with an intermediate connecting region, which are not connected to the cooling structure.

Advantageously, the edge region connects the connecting region. In particular, the inner surface may only comprise the edge region and the connecting region.

The cooling device, through which a fluid can flow, preferably further comprises (at least) a top plate and (at least) a base plate interconnected and defining the cooling channel. In this respect, the aforementioned inner surface of the wall of the cooling channel advantageously corresponds to at least one region of an inner side of the top plate or the base plate.

The top plate may preferably be level.

Preferably, the top plate and/or the base plate each have a constant thickness. The top plate and the base plate may have the same thickness or different thicknesses.

According to an advantageous exemplary embodiment, it is provided that the base plate, in particular as a deep-drawn sheet, comprises a recess that is covered by the top plate, such that the cooling channel is formed in the recess of the base plate between the base plate and the top plate. The cooling structure lies in this cooling channel. Thus, an easy to manufacture cooling device in a compact design is realized.

The top plate and/or the cooling structure and/or the base plate are preferably configured as sheet metal(s).

The top plate and the base plate advantageously form a housing of the cooling device. Preferably, the housing is composed only of the top plate and the base plate. This provides a simple, yet very compact cooling device with high cooling capacity. An internal space of the housing preferably corresponds at least in part, in particular entirely, to the cooling channel in which the cooling structure is located.

The top plate may preferably be shaped by punching. The base plane may preferably be manufactured by punching or deep drawing. The cooling structure may preferably be shaped by punching or rolling.

The cooling channel is preferably delimited or defined by a first wall, a second wall, a third wall and a fourth wall. The third wall and the fourth wall can advantageously be configured as lateral walls. The first wall may preferably form the top plate or a region of the top plate. The second wall, the third wall, and the fourth wall may form the base plate or a portion thereof. The aforementioned wall comprising the inner surface with the edge region preferably corresponds to the first wall or the second wall.

An inner surface of the first wall of the cooling channel and an inner surface of the second wall of the cooling channel are advantageously opposite each other. The inner surface of the first wall and the inner surface of the second wall are in particular preferably parallel, in particular plan parallel, to each other.

As already described, the inner surface of a wall of the cooling channel can comprise two edge regions. In particular, the inner surface of the first wall or the inner surface of the second of the cooling channel may comprise two edge regions that are not connected to the cooling structure. However, it is also possible for the inner surface of the first wall of the cooling channel and the inner surface of the second wall of the cooling channel to each have an edge region that is without connection to the cooling structure.

The cooling structure preferably has a region facing the inner surface, which has a surface facing/opposite the inner surface.

A portion of the surface is preferably opposite the edge region and is not connected to the edge region. That is, a portion of the surface is preferably opposite the connecting region and connected to the connecting region.

Particularly preferably, the cooling structure comprises a plurality of regions which face the inner surface and each have a surface facing/opposite the inner surface.

One of the surfaces is preferably at least partially, in particular entirely, opposite the edge region and not connected to the edge region. One of the surfaces is preferably at least partially, in particular completely, opposite the connecting region and connected to the connecting region.

According to an advantageous exemplary embodiment, the edge region may be in contact with the cooling structure. In particular, the aforementioned portion of the surface which is opposite the edge region and not connected to the edge region may contact the edge region. Preferably, the aforementioned surface, which is at least partially, in particular entirely opposite the edge region and not connected to the edge region, can contact the edge region. According to an alternative advantageous exemplary embodiment, a gap may be provided between the aforementioned portion of the surface opposite the edge region and not connected to the edge region. Preferably, a gap can be provided between the aforementioned surface, which is at least partially, in particular entirely, opposite the edge region and not connected to the edge region, and the edge region. It is to be understood that the gap is formed in a thickness direction of the cooling device. The thickness direction preferably corresponds to a direction in which the top plate is applied to the base plate.

According to an advantageous exemplary embodiment, the cooling structure can be arranged in the cooling channel without overlapping with the edge region. In other words, that no portion of the cooling structure is below/above the edge region or that no portion of the cooling structure is opposite the edge region. The cooling structure is thus only below/above the connecting region. It should be understood that the edge region of the inner surface of the wall of the cooling channel is advantageously created here by the cooling structure having a dimension in a direction perpendicular to the flow direction, in particular in the width direction of the cooling device, which is smaller than a corresponding dimension of the inner surface, and that the cooling structure is arranged in the cooling channel at a distance from one end of the inner surface. This distance corresponds to the dimension of the edge region in a direction relative to the flow of the fluid in the cooling channel, in particular the width direction of the cooling device. This distance is in particular to be understood as a minimum distance between one end of the inner surface and the cooling structure. As already described, the cooling structure can preferably have at least one region facing the inner surface, which has a surface facing/opposite the inner surface. In particular, the cooling structure comprises a plurality of regions which face the inner surface and each have a surface facing/opposite the inner surface.

In this case, the arrangement of the cooling structure in the cooling channel without overlap with the edge region means in particular that all such surfaces face/are opposite the connecting region.

A dimension of the edge region is preferably in a direction perpendicular to the flow direction of the fluid in the cooling channel of between 5 mm and 15 mm, more preferably 10 mm. Thus, an optimal balance between a stable arrangement of the cooling structure in the cooling channel and a reduction of stresses in the at least one connecting layer connecting the electrical and/or electronic assembly to the cooling device. The direction perpendicular to the direction flow of the fluid in the cooling channel preferably corresponds to a width direction of the cooling device and/or the cooling channel. In the embodiment in which the cooling structure in the cooling channel is arranged without overlap with the edge region, the distance, which corresponds to the dimension of the edge region in a flow direction of the fluid in the cooling channel, in particular the width direction of the cooling device, is therefore, preferably 5 mm to 15 mm, preferably 10 mm.

The edge region of the cooling device may preferably extend in the flow direction of the fluid in the cooling channel between a first end of the cooling structure and a second end of the cooling structure, in particular from the first end of the cooling structure to the second end of the cooling structure. That is to say that the edge region is preferably formed between only the first end and the second end of the cooling structure, in particular from only the first end of the cooling structure to the second end of the cooling structure.

The cooling device preferably comprises a receiving region for receiving an electrical and/or electronic assembly. According to an advantageous embodiment of the invention, the top plate may comprise the receiving region for receiving the electrical and/or electronic assembly. According to an alternative embodiment of the invention, the base plane may comprise the receiving region for receiving the electrical and/or electronic assembly.

It is also possible that both the top plate and the base plate each have such a receiving region. In this configuration, two electrical and/or electronic assemblies may be arranged on and cooled by the cooling device.

The receiving region of the top plate and/or the receiving region of the base plate can in particular be configured as support surface(s). The support surface is advantageously part of an outer surface of the respective component, i.e. the top plate or the base plate.

The edge region may preferably extend in the flow direction of the fluid in the cooling channel from the first end of the receiving region to the second end of the receiving region.

The cooling structure may preferably extend in the flow direction of the fluid in the cooling channel from the first end of the receiving region to the second end of the receiving region. In other words, the cooling structure is preferably only arranged in a region of the cooling channel that corresponds to or is associated with the receiving region or the electrical and/or electronic assembly. In particular, the cooling structure is arranged directly below the receiving region.

Preferably, the inner surface of the wall of the cooling channel may comprise a further edge region that extends in a flow direction of the fluid in the cooling channel and is not connected to the cooling structure. The connecting region is arranged between the two edge regions. That is, the inner surface of the wall of the cooling channel (only) comprises the two edge regions and the connecting region. The connecting region can in particular also be referred to as the middle region. According to an advantageous embodiment, the cooling structure is arranged entirely between the edge regions.

A dimension of the cooling structure in the direction perpendicular to the flow direction of the fluid may be less than a dimension of the receiving region and/or a dimension of the electrical and/or electronic assembly in the direction perpendicular to the flow direction of the fluid, in accordance with an advantageous exemplary embodiment. A dimension of the cooling structure in the direction perpendicular to the flow direction of the fluid may the same as a dimension of the receiving region and/or a dimension of the electrical and/or electronic assembly in the direction perpendicular to the flow direction of the fluid, in accordance with an alternative advantageous exemplary embodiment.

The cooling structure in the context of the present invention is preferably understood as a surface-enhancing, flow-conducting and heat-transfer-increasing structure.

The cooling structure is preferably configured as a turbulator (also referred to as a turbulence structure). That is, the cooling structure is configured to generate turbulent flows in the fluid flowing through the cooling channel. The cooling structure thus provides better heat dissipation from the cooling device to the fluid flowing through the cooling device. The cooling structure is in particular configured as a turbulence insert.

The cooling structure may preferably comprise a cooling fin structure and/or a pin structure (cooling pin structure). It is also conceivable that the cooling structure alternatively or additionally also comprises a cooling structure element or a plurality of cooling structure elements that have a different shape than a cooling fin or pin. It is in particular possible for the cooling structure to have a plurality of cooling structure elements of different shapes. For example, the cooling structure may comprise a cooling fin and a pin, or a plurality of cooling fins, and a plurality of pins. In the context of the present invention, a cooling fin and a pin may each be referred to as a cooling structure element.

The cooling fin structure may preferably comprise (only) a cooling fin or a plurality of cooling fins, which are preferably located one behind the other in the flow direction. The flow direction corresponds in particular to a main flow direction of a fluid used as a coolant, which flows through openings formed by the cooling fin(s). In particular, the main flow direction is in this case the direction in which the fluid mainly flows, i.e., the direction in which a velocity component of the fluid is greater than a velocity component of the fluid in a direction perpendicular to the main flow direction. The main flow direction may preferably correspond to a direction in which the fluid enters the cooler, through which fluid can flow. The main flow direction is preferably parallel to the longitudinal direction of the cooler.

The cooling fin is formed by a wave profile periodically repeating in a repeating direction. A pin structure may preferably comprise only one or a plurality of pins, which are preferably located in the flow direction and/or in a direction perpendicular to the flow direction.

The cooling structure may preferably be made, at least partially, particularly completely, of a material and/or coated with a material that features a coefficient of thermal conductivity greater than 200 W/(m K). Advantageously, the cooling structure may be, at least partially, in particular completely, made of aluminum or coated with aluminum. In particular, these configurations relate to the cooling structure elements of the cooling structure.

The entire cooling device, that is, the top plate, the base plate, and the cooling structure, may preferably be made of and/or coated from the same material, preferably aluminum or e.g. copper or stainless steel.

In the context of the present invention, the fluid flowing through the cooler may in particular also be referred to as coolant (cooling fluid). For example, water may be used as a coolant.

Furthermore, the present invention relates to an electrical and/or electronic device having a cooling device, through which fluid can flow, and an electrical and/or electronic assembly arranged on the cooling device.

The electrical and/or electronic device may in particular be a power electronics device comprising at least one power electronics assembly, in particular a plurality of power electronics assemblies. In the context of the invention, a power electronics unit can in particular also be referred to as a power module. The power electronics unit preferably comprises a carrier plate and/or conductor paths and/or one or a plurality of power semiconductors.

The power electronics component(s) are preferably joined to the cooling device, through which fluid can flow, in particular the top pate, part by means of a layer generated by a soft soldering process or a sintering process, which can thus be referred to as a soft soldering layer or a sintering layer, respectively. The soft soldering layer and the sintering layer are each to be understood as the aforementioned connecting layer.

Each power electronics component is preferably arranged on a receiving region, in particular support surface, of the cooling device associated with this power electronics component. That is to say, the number of receiving regions preferably corresponds to the number of power electronics components.

### BRIEF DESCRIPTION OF THE DRAWINGS

In the following sections, exemplary embodiments of the invention are described in detail with reference to the accompanying drawing, wherein identical or functionally identical components are each designated by the same reference number. The drawings show:

FIG. 1 a simplified schematic view of an electrical and/or electronic device according to the present invention with a cooling device, through which a fluid can flow, according to a first exemplary embodiment of the present invention in longitudinal section,

FIG. 2 a simplified schematic top plan view of a region of the electrical and/or electronic device of FIG. 1,

FIG. 3 a simplified cross-sectional schematic view of the electrical and/or electronic device of FIG. 1,

FIG. 4 a simplified schematic sectional view of an electrical and/or electronic arrangement according to a second exemplary embodiment of the invention,

FIG. 5 a simplified schematic plan view of a region of an electrical and/or electronic device according to the invention according to a third exemplary embodiment of the present invention, and

FIG. 6 a simplified schematic cross-sectional view of the electrical and/or electronic device according to the third exemplary embodiment of the present invention.

### DETAILED DESCRIPTION

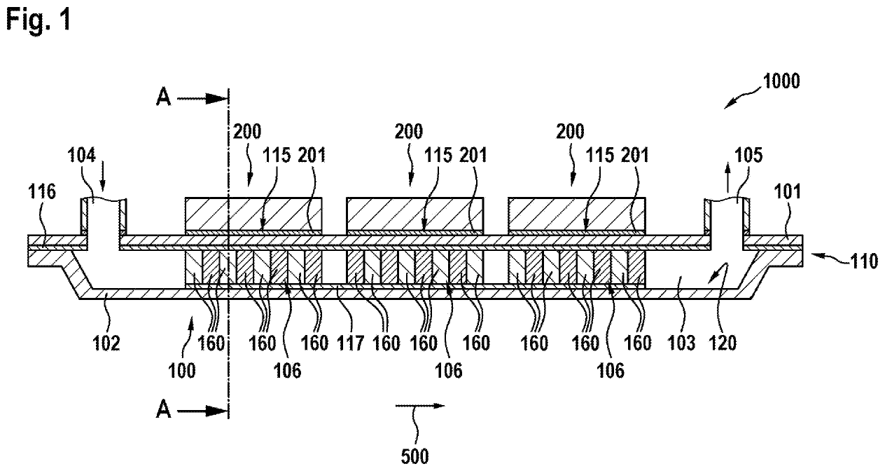

Referring now to FIGS. 1 to 3, an electrical and/or electronic device 1000 according to the present invention is described with a plurality of electrical and/or electronic assemblies 200 and a cooling device 100, through which a fluid can flow, for cooling the electrical and/or electronic assemblies 200 according to a first exemplary embodiment of the present invention.

In particular, in this exemplary embodiment, the electrical and/or electronic device 1000 comprises three electrical and/or electronic assemblies 200. However, the number of electrical and/or electronic assemblies 200 may vary. It is also possible that the electrical and/or electronic device 1000 may have only one electrical and/or electronic assembly 200.

In operation, heat is generated from the electrical and/or electronic assemblies 200, which must be dissipated to ensure efficient operation of the electrical and/or electronic assemblies. To this end, the electrical and/or electronic assembly 200 is arranged on the cooling device 100, through which a fluid can flow, in particular on a top plate 101 of the cooling device 100, so that the generated heat can be dissipated via the cooling device 100. In particular, each of the electrical and/or electronic assemblies 200 is arranged on a receiving region 115, in particular a support surface, formed on the top plate 101. Each of the receiving regions 115 corresponds to a region of the outer surface of the top plate 101 that is configured to receive the assembly 200 prior to attaching the respective electrical and/or electronic assembly 200 to the cooling device 100 and, after attaching the respective electrical and/or electronic assembly 200, actually receives this assembly 200. In the assembled state of the electrical and/or electronic assemblies 200, a respective receiving region 115 contacts the respective assembly 200.

In particular, between the cooling device 100, in particular each of the receiving regions 115, and each of the electrical and/or electronic assemblies 200, a separate connecting layer 201 is arranged on the cooling device 100 for fastening and thermal connection of the respective electrical and/or electronic assembly 200. However, it is also possible that all electrical and/or electronic assemblies 200 may be attached to the top plate 101 by means of a continuous connecting layer. A mediation layer can be advantageously located between each layer 201 and the cooling device 100, which layer is firmly connected to the cooling device 100 and enables wetting of the connecting layer 201. In particular, the mediation layer may be formed from copper or nickel. The mediation layer is an optional feature of the electrical and/or electronics device 1000 and can in particular be considered either as a separate part or as part of the cooling device 100.

In particular, the electrical and/or electronic device 1000 may be a power electronics assembly having electrical and/or electronic assemblies 200 configured as power modules. These can be, for example, power circuits, such as inverter structures or converter structures, of hybrid vehicles or electric vehicles. Each of the power modules may preferably include a carrier plate, conductor paths, and power semiconductors. The conductor tracks are designed in particular as copper conductor tracks, wherein the carrier plate may preferably be made of ceramic. The power semiconductors may be applied to the traces by means of a layer, in particular a soldered or sintered layer. The conductor tracks together with the carrier plate form a power substrate. In this case, each connecting layer 201 can be generated by a soft soldering process or a sintering process and thus can be a soft soldering layer or sintering layer by means of which the corresponding power module is joined to the cooling device 100, through which fluid can flow, and thereby is thermally bonded thereto. For this purpose, the cooling device 100, in particular the top plate 101, can be advantageously surface coated with materials suitable for a soft soldering process or a sintering process.

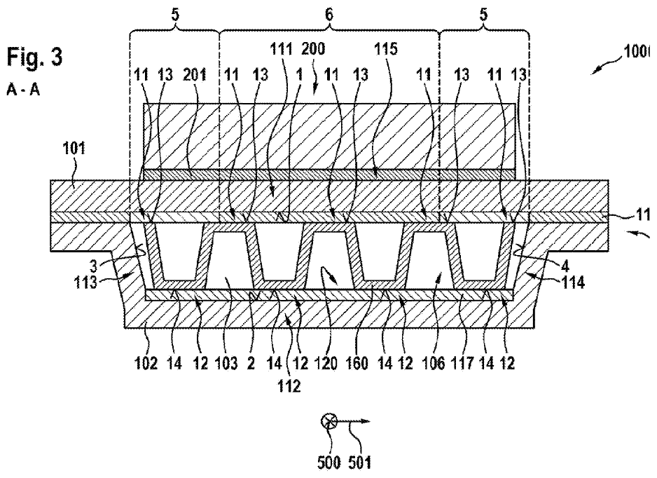

As can be seen from FIGS. 1 and 3, the cooling device 100, through which fluid can flow, comprises a base plate 102 in addition to the top plate 101. The top plate 101 and the base plate 102 are connected to each other, in particular, soldered. Advantageously, the top plate 101 and the base plate 102 may be connected to each other by means of a hard solder. Here, the top plate 101 forms an upper side of the cooling device 100 and the base plate 102 forms a lower side of the cooling device 100.

The top plate 101 and the base plate 102, which when assembled form a housing 110 of the cooling device 100, define an interior space in which a cooling channel 103 is formed. A fluid used as a coolant, in particular water, flows through the cooling channel 103 to dissipate heat generated by the electrical and/or electronic assemblies 200.

In particular, the top plate 101 is level, wherein the base plate 102 has a depression 120 covered by the top plate 101 such that the cooling channel 103 is formed in the depression 120 of the base plate 102 between the base plate 102 and the top plate 101. Thus, an easy to manufacture cooling device in a compact design is realized. To insert the fluid used as the coolant, an inlet 104 (FIG. 1) is arranged on the housing 110. An outlet 105 is formed on the housing 110 to remove the fluid (FIG. 1). The inlet 104 and the outlet 105 are advantageously formed as connecting pieces and are preferably joined by a solder, in particular hard solder, in the same manufacturing step in which the top plate 101 and the base plate 102 are connected to each other.

The ground plane 102 and the top plate 101 are formed as sheets and advantageously each have a constant thickness. The base plate 2 and the top plate 3 can in particular have the same thickness or also have different thicknesses. Specifically, the respective thickness also denotes a thickness of the respective output sheet from which the base plate 102 or top plate 103 is made. To form the depression 120 of the base plate 102, the base plate 102 can be advantageously manufactured by a deep drawing process.

From FIG. 3 it can be seen that the cooling channel 103 is in particular delimited or defined in the circumferential direction by a first wall 111, a second wall 112, a third wall 113 and a fourth wall 114. In particular, the third wall 113 and the fourth wall 114 are formed as lateral walls. The first wall 111 and the second wall 112 are opposite to each other and parallel to each other.

In particular, the cooling channel 103 is defined by corresponding inner surfaces of the first wall 111, the second wall 112, the third wall 113 and the fourth wall 114. The first wall 111 comprises a first inner surface 1, the second wall 112 comprises a second inner surface 2, the third wall 113 comprises a third inner surface 3, and the fourth wall 114 comprises a fourth inner surface 4. The first inner surface 1, the second inner surface 2, the third inner surface 3 and the fourth inner surface 4 are fully facing the cooling channel 103. The first inner surface 1 corresponds to a region of an inner side of the top plate 101, wherein the second inner surface 2, the third inner surface 3 and the fourth inner surface 4 each correspond to a region of an inner side of the base plate 102. The first inner surface 1 and the second inner surface 2 lie parallel to each other, in particular plan parallel.

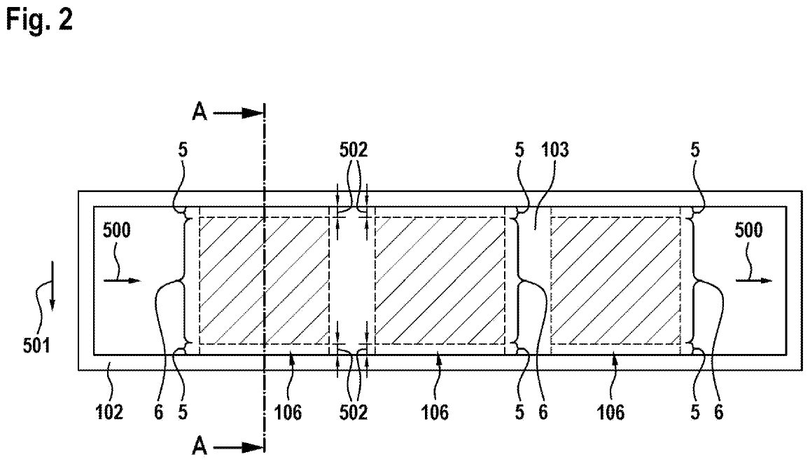

From FIGS. 1 and 2 it is taken that a separate cooling structure 106 is arranged in the cooling channel 103 for each electrical and/or electronic assembly 200, which serves as a surface-enhancing, flow-conducting and heat-transition-enhancing structure used as the coolant. That is to say, in this exemplary embodiment, three cooling structures 106 are arranged in the cooling channel 103.

Each cooling structure 106 is arranged directly below the respective electrical and/or electronic assembly 200 and extends in the flow direction 500 of the fluid in/through the cooling gallery 103 from a first end of the respective electrical and/or electronic assembly 200 to a second end of the respective electrical and/or electronic assembly 200, or from a first end of the respective receiving region 115 to a second end of the respective receiving region 115. Thus, targeted heat transfer from each electrical and/or electronic assembly 200 to its associated cooling structure 106 is enabled. However, it is also possible for a cooling structure 106 in the flow direction 500 of the fluid to be longer than the corresponding electrical and/or electronic assembly 200, or as the corresponding receiving region 115. However, the cooling structures 106 are arranged in the flow direction 500 of the fluid at a distance relative to each other. The flow direction 500 of the fluid advantageously corresponds to a longitudinal direction of the cooling device 100 and the cooling channel 103. The flow direction 500 in particular corresponds to a main flow direction of the fluid in/through the cooling channel 103.

The cooling structure 106 extends in particular across the entire width of the respective receiving region 115 and/or the respective electrical and/or electronic assembly 200. In other words, a dimension (a width) of each of the cooling structures 106 in the direction 501 perpendicular to the flow direction 500 of the fluid is less than the dimension (width) of the corresponding receiving region 115 or the corresponding electrical and/or electronic assembly 200 in the direction perpendicular to the flow direction 500 of the fluid 501.

In particular, each cooling structure 106 is configured as a cooling fin structure. To this end, the cooling fin structure has a plurality of cooling fins 160 arranged in the flow direction 500 of the fluid in/through the cooling channel 103 (FIG. 1). However, it is also possible for at least one of the cooling structures 106 to have a single cooling fin 160 extending from the first end of the respective electrical and/or electronic assembly 200 to the second end of the respective electrical and/or electronic assembly 200, or from the first end of the respective receiving region 115 to the second end of the respective receiving region 115.

FIG. 3 furthermore shows that the cooling fin 160 is formed from a wave profile that periodically repeats in a repetition direction. The repetition direction advantageously corresponds to a direction 501 perpendicular to the flow direction 500 of the fluid, or a width direction of the cooling device 100.

Each cooling structure 106 is preferably made of a material and/or coated with a material that features a thermal conductivity coefficient greater than 200 W/(m K). Advantageously, the cooling structures 106 may be made of aluminum or coated with aluminum. It is also possible that other thermally conductive materials are used for the cooling structures 106 and/or their layer.

At least two components of the cooling device 100, through which a fluid can flow and/or at least one component of the cooling device 100, through which a fluid can flow, and at least one component of the electrical and/or electronic assembly 200 have different thermal expansion coefficients. In particular, the top plate 101, which is in particular formed from a metallic material, can have a coefficient of expansion, which is in particular greater than a coefficient of expansion of the electrical and/or electronic assembly 200. Preferably, the top plate 101 and the base plate 102 are formed from aluminum, with the electronic and/or electronic assembly 200 having a different coefficient of thermal expansion than that of aluminum. As a result, upon thermal expansion/shrinkage of these components, in particular, the expansion/shrinkage of the top plate 101 is inhibited, which may cause the cooling device 100 to bend. Thus, stresses arise in the layers 201 connecting the electrical and/or electronic assemblies 200 to the cooling device 100, and in particular in the mediation layer(s), if any. Excessive stresses may cause cracks in the connecting layers 201, and in particular also in the mediation layer(s), which in turn may over time cause the electrical and/or electronic assemblies 200 to have no or only reduced thermal contact to the cooling device 100.

To avoid this, and thus to ensure good heat transfer between the electrical and/or electronic assemblies 200 and the cooling device 100, each of the cooling structures 106 is partially attached to the cooling device 100.

In particular, the first inner surface 1 comprises two edge regions 5 and a connecting region 6. The two edge regions 5 are not connected to the cooling structure 106, wherein the connecting region 6 is connected to the cooling structure 106. The connecting region 6 is in particular connected to the cooling structure 106 in a material-locking fashion. The connecting region 6 is arranged between the edge regions 5 and immediately adjoins the edge regions 5. That is to say, the first inner surface 1 comprises only the two edge regions 5 and the connecting region 6. The connecting region 6 is a central region of the first inner surface 1.

Each cooling rib 160 has a plurality of first regions 11 facing the first inner surface 1, wherein each of the first regions 11 have a surface 13 facing/opposite the first inner surface 1. The surfaces 13 of the first regions 11 are planar parallel to the first inner surface 1. Further, each cooling rib 160 has a plurality of second regions 12 facing the second inner surface 2, wherein each of the second regions 12 have a surface 14 facing the second inner surface 2. The surfaces 14 of the second regions 12 are plan parallel to the second inner surface 2.

The fact that the edge regions 5 are not connected to the cooling structure 106 means that those first surfaces 13 or parts thereof facing the edge regions 5 are not connected to the edge regions 5. In particular, the first surfaces 13 facing the edge regions 5 or parts thereof may contact the edge regions 5, wherein a relative movement between the first surfaces 13 or parts thereof facing the edge regions 5 is possible. The first surfaces 13 or parts thereof facing the connecting region 6 are connected to the connecting region 6.

The connecting region 6 is connected to the cooling structure 106 by means of a soldering layer 116, in particular a hard soldering layer. To prevent a connection between the edge regions 5 of the first inner surface 1 and the cooling structure 106, in particular the first surfaces 13 facing the edge regions 5, a solder stop paste can be used locally at the edge regions 5, for example in the manufacture of the cooling device 100. Alternatively, it is also possible to impinge the edge regions 5 so that a gap between the edge regions 5 and the cooling structure 106, in particular the first surfaces 13 facing the edge regions 5, becomes too large to be filled with solder. Here, the edge regions 5 do not contact the cooling structure 106. The soldering layer 116 extends in the width direction of the cooling device 100, preferably over the entire first inner surface 1 and in particular also over the entire inner side of the top plate 101, such that the soldering layer 116 also connects the top plate 101 to the base plate 102. It is noted that although the soldering layer 116 extends in the width direction of the cooling device 100 preferably across the whole first inner surface 1, the edge regions 5 are without connection to the cooling structure 106, as already described.

In the sectional view of the cooling device 100 shown in FIG. 3, the cooling rib 160 comprises five first regions 11 and thus also five first surfaces 13. As can be seen from FIG. 3, a complete first surface 13 and in some cases a further first surface 13 face each edge region 5 and are not connected to it. However, this may vary depending on the configuration of the cooling structure 106 or cooling structures 160 and cooling channel 103.

The cooling structure 106 is further connected to the base plate 102 by means of a soldering layer 117, in particular a hard soldering layer. Connecting the cooling structure 106 to the top plate 101 and the base plate 102 and connecting the top plate 101 to the base plate 102 can occur in the same manufacturing step.

By partially connecting the cooling structure 106 to the top plate 101, stresses that may arise during operation of the electrical and/or electronic assemblies 200 due to the different coefficients of expansion of the various components of the electrical and/or electronic device 1000 in the connecting layers 201 can be reduced.

This is achieved in particular by the fact that, due to the partial connection of the cooling structure 106 to the top plate 101, the components of the electrical and/or electronic device 1000 do not experience a less expansion/shrinkage that is so strongly blocked from one another. Thus, a stable connection of the electrical and/or electronic assemblies 200 to the top plate 101 can be achieved. At the same time, heat is transferred from the electrical and/or electronic assemblies 200 via the connecting layers 201 to the top plate 201 and from there via the soldering layer 116 to the cooling structure 106 and is discharged from the fluid flowing through the cooling channel 103.

In order to enable an optimal balance between a stable connection of the electrical and/or electronic assemblies 200 to the top plate 201 and a good removal of the heat generated by the electrical and/or electronic assemblies 200 via the cooling structure 106, a dimension 502 of each edge region 5 in the direction 501 perpendicular to the flow direction is between 5 mm and 15 mm, preferably 10 mm.

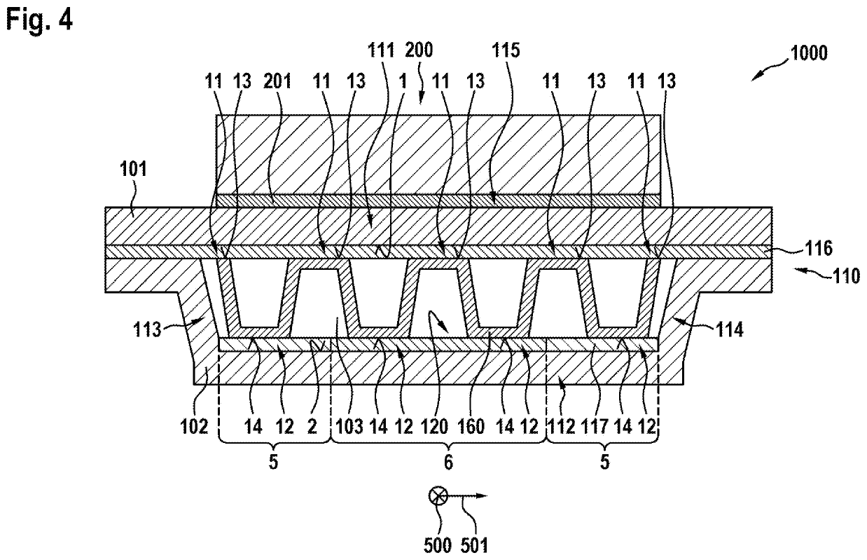

FIG. 4 relates to an electrical and/or electronic device 1000 according to the invention having a cooling device 100, through which a fluid can flow, according to a second exemplary embodiment of the present invention.

The electrical and/or electronic device 1000 according to the second exemplary embodiment is different from that according to the first exemplary embodiment by the connection of the cooling structures 106 to the housing 110 of the cooling device 100.

As can be seen from FIG. 4, instead of the first inner surface 1 of the first wall 111 of the cooling channel 103, the second inner surface 2 of the second wall 112 comprises two edge regions 5 which are configured like the edge regions 5 of the first inner surface 1 in the first exemplary embodiment.

In other words, in the cooling device 100, through which a fluid can flow, according to the second exemplary embodiment, each cooling structure 106 is partially connected to the base plate 102. The advantages described with reference to the cooling device 100 in accordance with the first exemplary embodiment also apply to the cooling device 100 or the electrical and/or electronic device 1000 in accordance with the second exemplary embodiment.

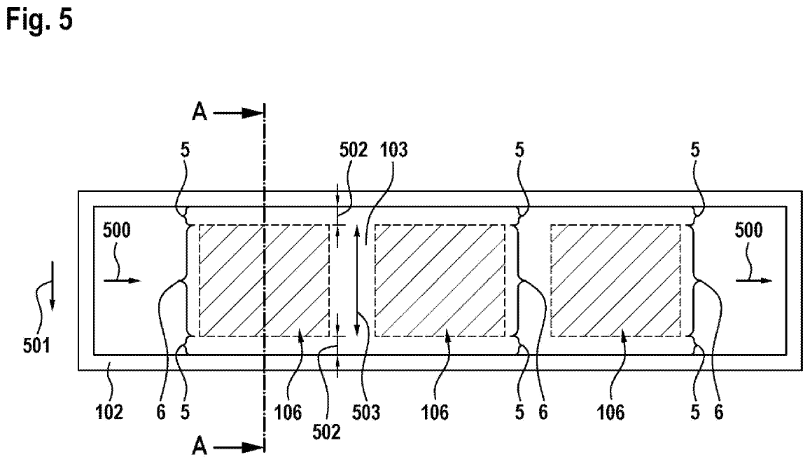

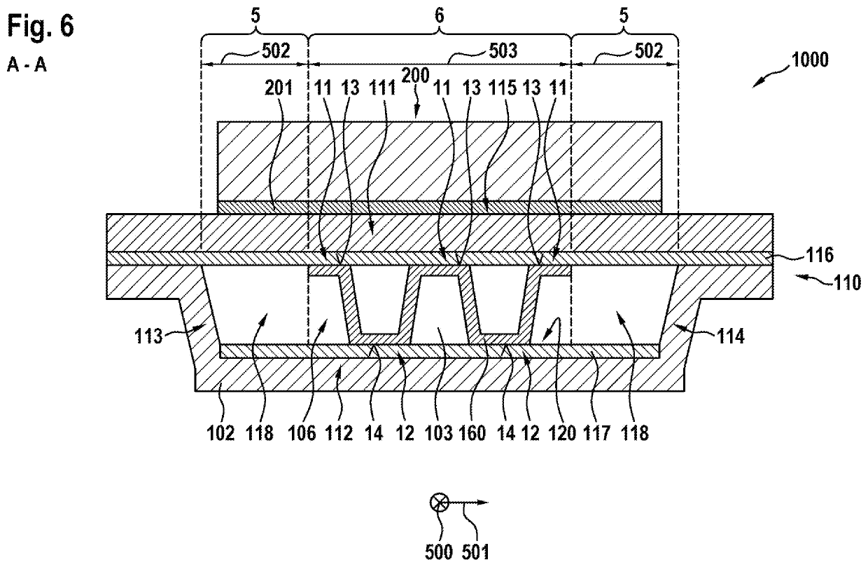

FIGS. 5 and 6 relate to an electrical and/or electronic device 1000 according to the present invention having a cooling device 100, through which a fluid can flow, according to a third exemplary embodiment of the present invention.

The electrical and/or electronic device 1000 according to the third exemplary embodiment is different from that according to the first exemplary embodiment by the configuration of the cooling structures 106 and their connection to the housing 110 of the cooling device 100.

In the third exemplary embodiment, each cooling structure 106 is arranged without overlap with the edge regions 106 of the first inner surface 1. That is to say, no part of a particular cooling structure 106 is below the edge regions 5, or no part of the cooling structure 106 is opposite the edge regions. The cooling structure 106 is thus only located below the connecting region 6. In this case, all first surfaces 13 face the connecting region 6 and are connected thereto.

It is to be understood that the edge regions 5 of the first inner surface 1 of the first wall 111 of the cooling channel 103 are formed by the cooling structure 106 having a dimension 503 (a width) in the direction 501 perpendicular to the flow direction 500 of the fluid or in the width direction of the cooling device 100, which is less than a corresponding dimension (a width) of the first inner surface 1 in the direction 501 perpendicular to the flow direction 500 of the fluid, and that the cooling structure 106 is arranged in the cooling channel 103 at a distance from the ends of the first inner surface 1 in the direction 501 perpendicular to the flow direction 500. The dimension (width) of the first inner surface 1 in the direction 501 perpendicular to the flow direction 500 of the fluid corresponds to the sum of the corresponding dimensions 502 (width) of the edge regions 5 and a corresponding dimension (width) of the connecting region 6.

The aforementioned distance between each end of the first inner surface 1 and the cooling structure 106 corresponds to the dimension 502 of the respective edge region 5 in the flow direction 500 of the fluid in the cooling channel 103. That is, the distance is between 5 mm and 15 mm, preferably 10 mm. The distance between each end of the first inner surface 1 and the cooling structure 106 corresponds to the minimum distance between the end of the first inner surface 1 and the cooling structure 106.

The cooling structure 106 extends in particular across the entire width of the respective receiving region 115 and/or the respective electrical and/or electronic assembly 200. In other words, a width of each of the cooling structures 106 is less than the width of the respective receiving region 115 and/or of the respective electrical and/or electronic assembly 200. This creates two bypass passages 118 for the fluid.

As a result of the described configuration of the cooling structure 106 and its arrangement in the cooling channel 103, the electrical and/or electronic device 1000 according to the third exemplary embodiment also realizes the advantages mentioned with reference to the first and second exemplary embodiments.

1. A cooling device (100), through which a fluid can flow, for cooling an electrical and/or electronic assembly (200), comprising:
a cooling channel (103), through which a fluid can flow, and
a cooling structure (106), which is arranged in the cooling channel (103), wherein an inner surface (1; 2) of a wall (111; 112) of the cooling channel (103) has a connecting region (6) and an edge region (5), wherein the connecting region (6) is connected to the cooling structure (106), and the edge region (5) is not connected to the cooling structure (106).

2. The cooling device (100), through which a fluid can flow, according to claim 1, wherein the edge region (5) connects to the connecting region (6).

3. The cooling device (100), through which a fluid can flow, according to claim 1, further comprising a top plate (101) and a base plate (102) interconnected and defining the cooling channel (103), wherein the inner surface (1; 2) is at least one portion of an inner side of the top plate (101) or an inner side of the base plate (102).

4. The cooling device (100), through which a fluid can flow, according to claim 1, wherein the cooling structure (106) has at least one region (11; 12) facing the inner surface (1; 2), which region comprises a surface (13; 14) facing the inner surface (1; 2), wherein a portion of the surface (13; 14) is opposite the edge region (5) and is not connected to the edge region (5).

5. The cooling device (100), through which a fluid can flow, according to claim 1, wherein the edge region (5) is in contact with the cooling structure (106).

6. The cooling device (100), through which a fluid can flow, according to claim 1, wherein the cooling structure (106) is arranged in the cooling channel (103) without overlap with the edge region (5).

7. The cooling device (100), through which a fluid can flow, according to claim 1, wherein a dimension (502) of the edge region (5) in a direction (501) perpendicular to a flow direction (500) of the fluid in the cooling channel (103) is between 5 mm and 15 mm.

8. The cooling device (100), through which a fluid can flow, according to claim 1, wherein the edge region (5) in a flow direction (500) of the fluid in the cooling channel (103) extends between a first end of the cooling structure (106) and a second end of the cooling structure (106).

9. The cooling device (100), through which a fluid can flow, according to claim 1, further comprising a receiving region (115) for receiving an electrical and/or electronic assembly (200).

10. The cooling device (100), through which a fluid can flow, according to claim 9, wherein the edge region (5) extends in a flow direction (500) of the fluid in the cooling channel (103) from a first end of the receiving region (115) to a second end of the receiving region (115), and/or
wherein the cooling structure (106) extends in the flow direction (500) of the fluid in the cooling channel (103) from a first end of the receiving region (115) to a second end of the receiving region (115).

11. The cooling device (100), through which a fluid can flow, according to claim 1, wherein the internal surface (1; 2) of the wall (101; 102) of the cooling channel (103) comprises a further edge region (5) extending in a flow direction (500) of the fluid in the cooling channel (103) and is not connected to the cooling structure (106), wherein the connecting region (6) is arranged between the two edge regions (5).

12. An electrical and/or electronic device (1000) comprising a cooling device (100), through which a fluid can flow, according to claim 1, and an electrical and/or electronic assembly (200) arranged on the cooling device (100), through which a fluid can flow.

13. The cooling device (100), through which a fluid can flow, according to claim 7, wherein the dimension (502) of the edge region (5) in the direction (501) perpendicular to the flow direction (500) of the fluid in the cooling channel (103) is 10 mm.

14. The cooling device (100), through which a fluid can flow, according to claim 1, wherein the edge region (5) in the flow direction (500) of the fluid in the cooling channel (103) extends entirely from the first end of the cooling structure (106) to the second end of the cooling structure (106).
